(19) United States
(12) Patent Application Publication
(10) Pub. No.: US 2014/0246741 A1
(43) Pub. Date: Sep. 4, 2014

(54) MAGNETORESISTIVE MEMORY CELL AND METHOD OF MANUFACTURING THE SAME

(71) Applicant: Yimin Guo, SAN JOSE, CA (US)

(72) Inventor: Yimin Guo, SAN JOSE, CA (US)

(73) Assignee: T3MEMORY, INC., Saratoga, CA (US)

(21) Appl. No.: 14/194,742

(22) Filed: Mar. 2, 2014

Related U.S. Application Data
(60) Provisional application No. 61/771,857, filed on Mar. 3, 2013.

(51) Int. Cl. H01L 43/02; H01L 43/12

(52) U.S. Cl. CPC H01L 43/02; H01L 43/12
USPC 257/421; 438/3

(57) ABSTRACT

A STT-MRAM comprises apparatus and a method of manufacturing a spin-torque magnetoresistive memory and a plurality of a three-terminal magnetoresistive memory element having a voltage-gated recording. The first terminal, a bit line, is connected to the top magnetic reference layer, and the second terminal is located at the middle recording layer which is connected to the underneath select CMOS transistor through a VIA and the third one, a digital line, is a voltage gate with a narrow pillar underneath the memory layer across an insulating functional layer which is used to reduce the write current by manipulating the perpendicular anisotropy of the recording layer. The fabrication includes formation of a bottom electrode, formation of digital line, formation of memory cell & VIA connection and formation of the top bit line. Photolithography patterning and hard mask etch are used to form the digital line pillar and small memory pillar. Ion implantation is used to convert a buried dielectric layer outside the center memory pillar into an electric conductive path between middle recording layer and underneath CMOS transistor.

### RELATED APPLICATIONS

This application claims the priority benefit of U.S. Provisional Application No. 61,771,857 filed on Mar. 3, 2013, which is incorporated herein by reference.

### BACKGROUND OF THE INVENTION

1. Field of the Invention

This invention relates generally to a three terminal magnetic-random-access memory (MRAM) cell, more particularly to methods of fabricating three terminal MRAM memory elements having ultra-small dimensions.

2. Description of the Related Art

In recent years, magnetic random access memories (hereinafter referred to as MRAMs) using the magnetoresistive effect of ferromagnetic tunnel junctions (also called MTJs) have been drawing increasing attention as the next-generation solid-state nonvolatile memories that can also cope with high-speed reading and writing. A ferromagnetic tunnel junction has a three-layer stack structure formed by stacking a recording layer having a changeable magnetization direction, an insulating tunnel barrier layer, and a fixed layer that is located on the opposite side from the recording layer and maintains a predetermined magnetization direction. Corresponding to the parallel and anti-parallel magnetic states between the recording layer magnetization and the reference layer magnetization, the magnetic memory element has low and high electrical resistance states, respectively. Accordingly, a detection of the resistance allows a magnetoresistive element to provide information stored in the magnetic memory device.

There has been a known technique for achieving a high MR ratio by forming a crystallization acceleration film that accelerates crystallization and is in contact with an interfacial magnetic film having an amorphous structure. As the crystallization acceleration film is formed, crystallization is accelerated from the tunnel barrier layer side, and the interfaces with the tunnel barrier layer and the interfacial magnetic film are matched to each other. By using this technique, a high MR ratio can be achieved.

Typically, MRAM devices are classified by different write methods. A traditional MRAM is a magnetic field-switched MRAM utilizing electric line currents to generate magnetic fields and switch the magnetization direction of the recording layer in a magnetoresistive element at their cross-point location during the programming write. A spin-transfer torque (or STT)-MRAM has a different write method utilizing electrons' spin momentum transfer. Specifically, the angular momentum of the spin-polarized electrons is transmitted to the electrons in the magnetic material serving as the magnetic recording layer. According to this method, the magnetization direction of a recording layer is reversed by applying a spin-polarized current to the magnetoresistive element. As the volume of the magnetic layer forming the recording layer is smaller, the injected spin-polarized current to write or switch can be also smaller.

Besides a write current, the stability of the magnetic orientation in a MRAM cell as another critical parameter has to be kept high enough for a good data retention, and is typically characterized by the so-called thermal factor which is proportional to the energy barrier as well as the volume of the recording layer cell size.

To record information or change resistance state, typically a recording current is provided by its CMOS transistor to flow in the stacked direction of the magnetoresistive element, which is hereinafter referred to as a “vertical spin-transfer method.” Generally, constant-voltage recording is performed when recording is performed in a memory device accompanied by a resistance change. In a STT-MRAM, the majority of the applied voltage is acting on a thin oxide layer (tunnel barrier layer) which is about 10 angstroms thick, and, if an excessive voltage is applied, the tunnel barrier breaks down. More, even when the tunnel barrier does not immediately break down, if recording operations are repeated, the element may still become nonfunctional such that the resistance value changes (decreases) and information readout errors increase, making the element un-recordable. Furthermore, recording is not performed unless a sufficient voltage or sufficient spin current is applied. Accordingly, problems with insufficient recording arise before possible tunnel barrier breaks down.

In the mean time, since the switching current requirements reduce with decreasing MTJ element dimensions, STT-MRAM has the potential to scale nicely at even the most advanced technology nodes. However, patterning of small MTJ element leads to increasing variability in MTJ resistance and sustaining relatively high switching current or recording voltage variation in a STT-MRAM.

Reading STT MRAM involves applying a voltage to the MTJ stack to discover whether the MTJ element states at high resistance or low. However, a relatively high voltage needs to be applied to the MTJ to correctly determine whether its resistance is high or low, and the current passed at this voltage leaves little difference between the read-voltage and the write-voltage. Any fluctuation in the electrical characteristics of individual MTJs at advanced technology nodes could cause what was intended as a read-current, to have the effect of a write-current, thus unintentionally reversing the direction of magnetization of the recording layer in MTJ.

Above issues or problems are all associated with the traditional two-terminal MRAM configuration. Thus, it is desirable to provide robust STT-MRAM structures and methods that realize highly-accurate reading, highly-reliable recording and low power consumption while suppressing destruction and reduction of life of MTJ memory device due to recording in a nonvolatile memory that performs recording resistance changes, and maintaining a high thermal factor for a good data retention.

### BRIEF SUMMARY OF THE PRESENT INVENTION

The present invention comprises methods of making a low power spin-transfer-torque MRAM comprising a three terminal magnetoresistive memory cell, which has three terminals: an upper electrode connected to a bit line, a middle electrode connected to a select transistor and a digital line as a bottom electrode wherein an MTJ stack is sandwiched between an upper electrode and a middle electrode, a dielectric functional layer is sandwiched between a middle electrode and a digital line of each MRAM memory cell.

The memory cell further includes a circuitry coupled to the bit line positioned adjacent to selected ones of the plurality of magnetoresistive memory elements to supply a reading current or bi-directional spin polarized current to the MTJ stack, and coupled to the digital line configured to generate an electric field on the functional layer and accordingly to decrease the switching energy barrier of the recording layer. Thus magnetization of a recording layer can be readily switched or reversed to the direction in accordance with a direction of a current across the MTJ stack by applying a low spin transfer current.

The fabrication method of the MRAM cell includes formation of bottom electrode, formation of middle electric connecting layer, formation of magnetic memory cell and formation of top electrode and bit line, by repeated film deposition, photolithography patterning, etching, dielectric refilling and chemical mechanic lapping, in which metallic ion implantation is used to convert the isolated middle layers into electrically conducting layer to allow the current flow between middle magnetic recording layer and bottom electrode.

The exemplary embodiment will be described hereinafter with reference to the companying drawings. The drawings are schematic or conceptual, and the relationships between the thickness and width of portions, the proportional coefficients of sizes among portions, etc., are not necessarily the same as the actual values thereof.

### BRIEF DESCRIPTION OF THE DRAWINGS

FIG. 1 is a cross section view of one memory cell having three terminals in a STT-MRAM array;

FIG. 2 is a process flow to make three-terminal memory;

FIG. 3(A, B) are a cross section view and a top view of a substrate, respectively, with CMOS built-in (not shown) and VIA to connect to the top magnetic memory cell to be built;

FIG. 4 illustrates a bottom electrode formed on the substrate and connected to the VIA;

FIG. 5(A, B) are a cross section view and a top view of the bottom electrode is formed by patterning, etch and dielectric refill and CMP;

FIG. 6 shows that a bottom dielectric layer and a digital line film stack are deposited subsequently on the bottom electrode;

FIG. 7(A, B) are a cross section view and a top view of the digital line top pillar formed by patterning and reactive ion etch;

FIG. 8(A, B) are a cross section view and a top view of the digital line base portion formed by patterning and reactive ion etch;

FIG. 9 is a cross section view of the structure of the digital line having dielectric refilled and CMP to flatten the surface;

FIG. 10(A, B) are a cross section view and a top view of the bottom electrode patterned and RIE etched to open a spacing for a bottom connection layer;

FIG. 11a cross section view of the bottom connection layer formed in the open space;

FIG. 12(A, B) are a cross section view and a top view of the digital line formed by a patterning, etch, dielectric refill and CMP;

FIG. 13 shows a TMR film stack deposited on top of digital line surface;

FIG. 14 is a cross section view of a memory pillar formed by patterning, etch and ALD refill;

FIG. 15 is a cross section view of the structure after a metal ion implantation is used to dope metal ions into the un-etched memory film stack including the buried insulating layer;

FIG. 16(A, B) are a cross section view and a top view of the middle electric connection base is formed by patterning, etch, dielectric refill and CMP;

FIG. 17(A, B) are a cross section view and a top view of the structure after a top bit line formed by film stack deposition, patterning, etch, dielectric refill and CMP.

### DETAILED DESCRIPTION OF THE INVENTION

In general, there is provided a magnetoresistive memory cell comprising:
a bottom electrode provided on a surface of a substrate and coupled a select transistor through a conductive VIA;
a first interlayer dielectric layer provided on a surface of the bottom electrode;
a digital line provided on a surface of the interlayer dielectric layer;
a second dielectric layer provided on side walls of the digital line;
a dielectric functional layer provided on the top surface of the digital line layer;
a recording layer provided on the top surface of the dielectric functional layer having a magnetic anisotropy and a variable magnetization direction and having an induced perpendicular anisotropy from a interface interaction with the functional layer;
a bottom connection layer provided on outside walls of the second dielectric layer and electrically connecting the recording layer and the bottom electrode;
a tunnel barrier layer provided on the top surface of the recording layer;
a reference layer provided on the top surface of the tunnel barrier having magnetic anisotropy and having a fixed magnetization direction;
a cap layer provided on the top surface of the reference layer as an upper electric electrode;
a bit line provided on the top surface of the cap layer;
a CMOS transistor coupled the plurality of magnetoresistive memory elements through the bottom electrode.
There is further provided circuitry connected to the bit line, the digital line and the select transistor of each magnetoresistive memory cell.

A dielectric functional layer is made of a metal oxide (or nitride, chloride) layer having a naturally stable rocksalt crystal structure having the (100) plane parallel to the substrate plane and with lattice parameter along its {110} direction being larger than the bcc(body-centered cubic)-phase Co lattice parameter along {100} direction. As an amorphous ferromagnetic material, like CoFeB, in the recording layer is thermally annealed, a crystallization process occurs to form bcc CoFe grains having epitaxial growth with (100) plane parallel to surface of the rocksalt crystal functional layer.

In a rocksalt crystal structure of a functional layer, such as MgO, two fcc sublattices for metal atoms and O atoms, each displaced with respect to the other by half lattice parameter along the [100] direction. However, at a surface, O atoms protrude while metal atoms retreat slightly from the surface, forming a strong interface interaction with the bcc CoFe grains. Accordingly, a perpendicular anisotropy and a perpendicular magnetization are induced in the recording layer, as a result of the strong interface interaction between the recording layer and the functional layer.

Further, as an electric field is applied on the functional layer and perpendicular to the surface, the negative charged O atoms and positive charged metal atoms at surface are pulled toward opposite directions and modify the interface interaction between the bcc CoFe grains in the soft adjacent layer and the rocksalt crystal grains in the functional layer. When an electric field points down towards the top surface of a functional layer, O atoms protrude more from the surface and form a stronger interface interaction with the bcc CoFe grains, causing an enhanced perpendicular anisotropy, and vice versa. This mechanism is utilized hereafter to manipulate the perpendicular anisotropy strength and magnetization direction of the recording layer through applying an electric field on the dielectric functional layer.

An exemplary embodiment includes method of fabricating a spin-transfer-torque magnetoresistive memory including a circuitry coupled to the bit line positioned adjacent to selected ones of the plurality of magnetoresistive memory elements to supply a reading current or bi-directional spin-transfer recording current, and coupled to the digital line configured to generate an electric field on the functional layer and accordingly to manipulate the perpendicular anisotropy strength of the recording layer. Thus magnetization of a recording layer can be readily switched or reversed to the direction in accordance with a direction of a current across the MTJ stack by applying a low spin transfer current.

The following detailed descriptions are merely illustrative in nature and are not intended to limit the embodiments of the subject matter or the application and uses of such embodiments. Any implementation described herein as exemplary is not necessarily to be construed as preferred or advantageous over other implementations. Furthermore, there is no intention to be bound by any expressed or implied theory presented in the preceding technical field, background, brief summary, or the following detailed description.

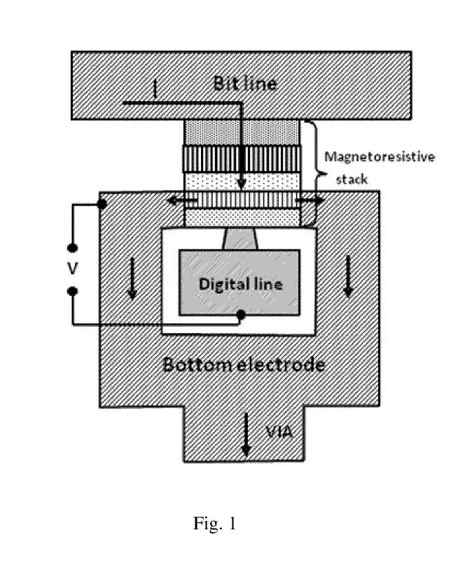

FIG. 1 is a schematic view of a three-terminal voltage-gated magnetoresistive memory cell comprising a bottom electrode directly on top of a VIA to a select transistor (which is not shown here), a bottom connection layer connecting the bottom electrode and a memory recording layer, a digital line surrounded by a bottom dielectric layer which is on top of the bottom electrode and a side dielectric layer. The magnetoresistive stack consists of a cap layer, a fixed reference layer, a tunnel barrier layer, a recording layer and a bottom insulating functional layer, in an order from top to bottom. A bit line is built to electrically connect to the top of the magnetoresisitive stack. The recording layer is connected to the bottom electrode through the bottom connection layer and further connected to a select CMOS transistor (not shown here) through a VIA. The MTJ stack is a perpendicular MTJ or a planar MTJ. In another word, both the magnetic reference layer and the recording layer have perpendicular anisotropies and magnetizations or planar anisotropy and magnetizations. The top magnetic reference layer has a fixed magnetization due to its strong anisotropy; while the anisotropy of the memory recording layer can be either perpendicular to the film plane or in the plane depending on the voltage applied on the functional layer between middle memory recording layer and bottom digital line pillar. Both read and write current flow through the top reference layer, the tunnel barrier layer, the memory recording layer, the bottom connection layer, the bottom electrode and the VIA to or from the underneath CMOS control circuit (not shown here). The write current can be greatly reduced by a voltage applied between the digital line and bottom electrode.

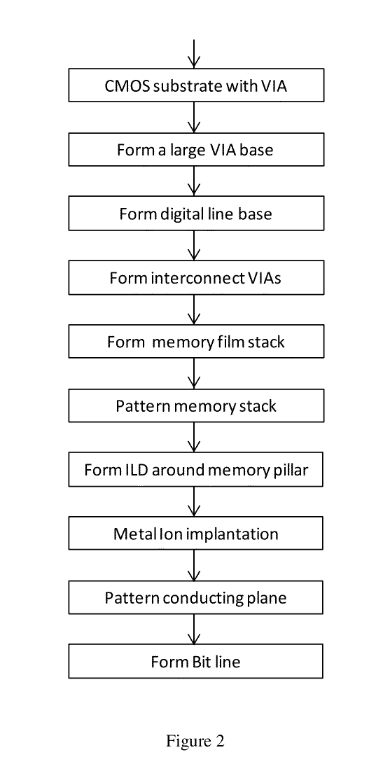

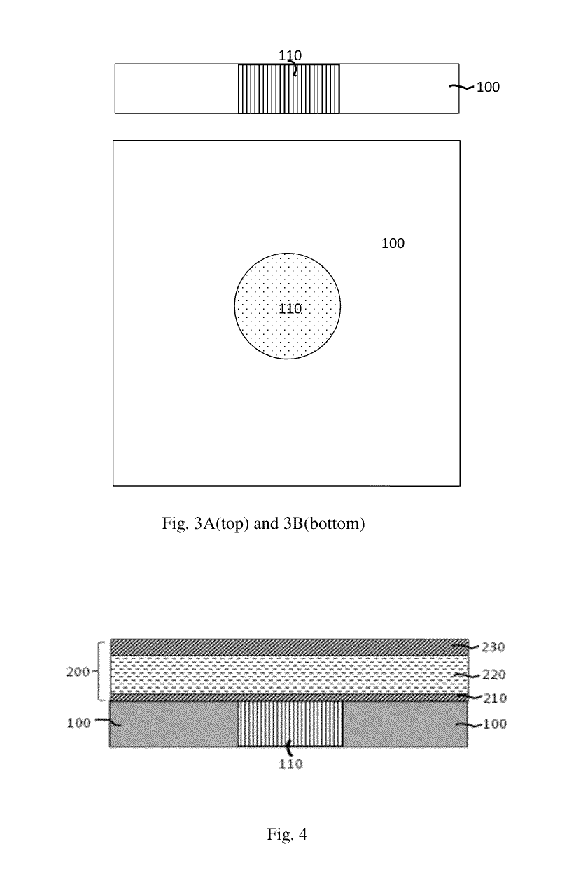

A fabrication process to form such a three-terminal memory device is shown in the process flow chart in FIG. 2. A substrate 100, as shown in FIG. 3, contains a VIA 110 which is connected to a select CMOS transistor already built (not shown). The process starts from the deposition of metallic multilayer with a typical film stack 200 of Ta 210/Ru or Cu, other highly conductive material layer 220/Ta 230 in FIG. 4, to form a large bottom electrode base to accommodate the digital line in the middle. Typical thicknesses of these layers are 5 nm for a Ta layer 210, 40 nm for a Ru layer 220 and 20 nm Ta layer 230, respectively.

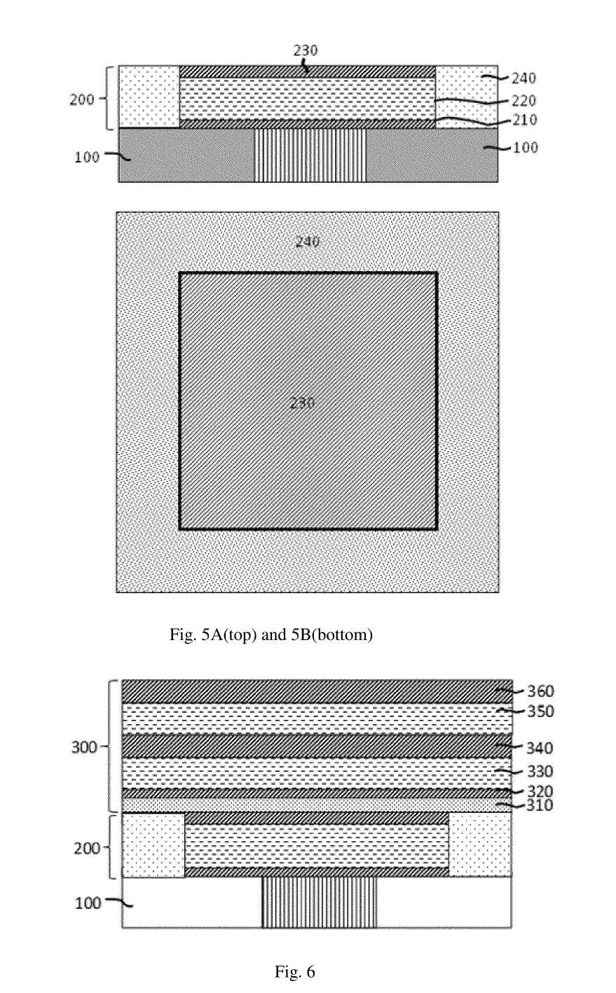

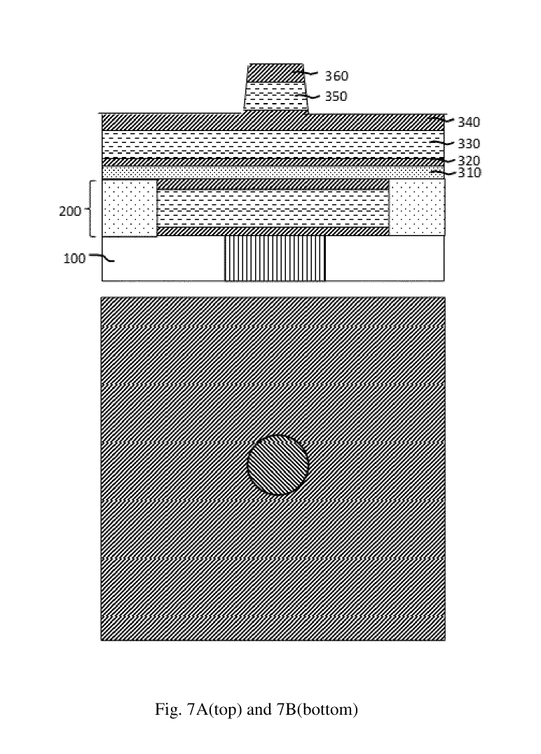

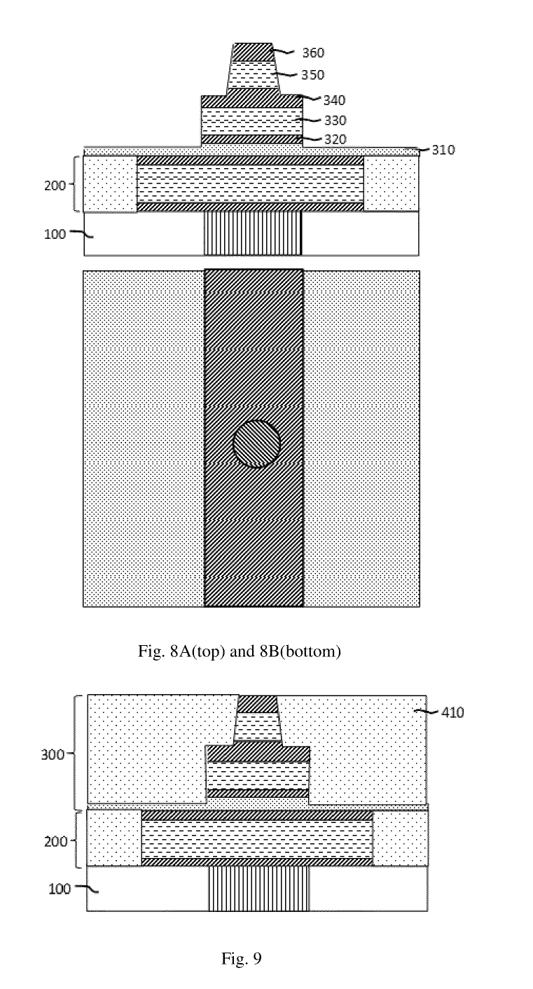

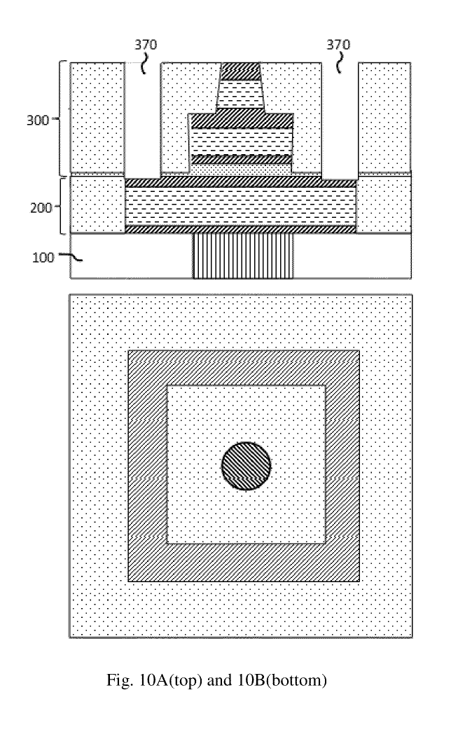

By photolithography patterning, etch, dielectric refill of a SiO2 layer 240 and CMP, as shown in FIG. 5, an isolated metal base is formed, as a bottom electrode, which connects to the underneath VIA. Then, a film stack 300 of ILD/Ta/Ru/Ta/Ru/Ta is deposited, as shown in FIG. 6, for a digital line and its top pillar. The bottom ILD layer 310 serves to isolate the film stack 300 from the bottom electrode base layer 200. Examples of film thicknesses are 10 nm for the ILD layer 310, 5 nm for the Ta layer 320, 40 nm for the Ru layer 330, 20 nm for the Ta layer 340, 40 nm for the Ru layer 350, and 20 nm for the Ta layer 360. FIG. 7 shows that a top conducting pillar is formed by a single or dual photolithography patterning and RIE to form a small Ta hard mask 360 using a chemical gas (such as CF4, CHF3), and then etch through the Ru layer 350 using a mixed gas of CH3OH or CO & NH4 chemical gases, and stopped on the middle Ta layer 340. Then, another similar photolithography patterning and RIE (stopped in the middle of bottom insulating layer-310) to form a long stripe digital line with a smaller conducting pillar above, as shown in FIG. 8. Then, a dielectric SiO2 layer 410 is deposited and flattened by CMP to cover the entire surface, as shown in FIG. 9.

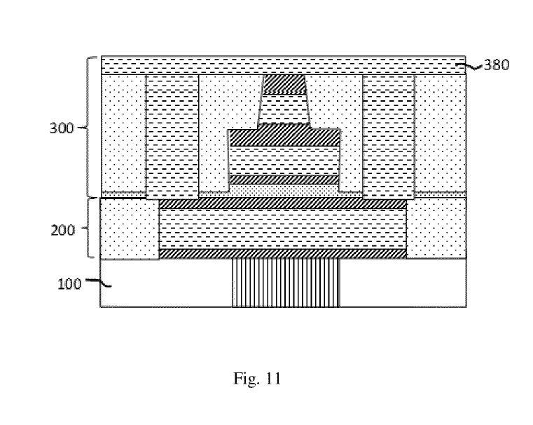

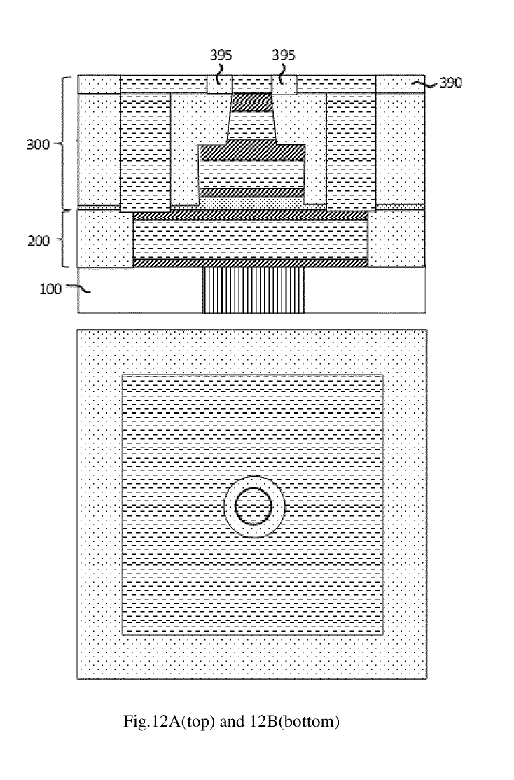

Another photolithography patterning and etch are used to open a space down to the bottom electrode, as shown 370 in FIG. 10, and a metal (Cu & Al alloy or Ru) layer is formed conformally to form electric conductive paths between the bottom electrode and the recording layer 380, as shown in FIG. 11, to be built. The conformal metal formation method can be either plating or atomic layer deposition (ALD). To isolate the middle digital line pillar from the memory cell, another photolithography patterning, etch and dielectric refill and CMP are used, as shown by 395 in FIG. 12.

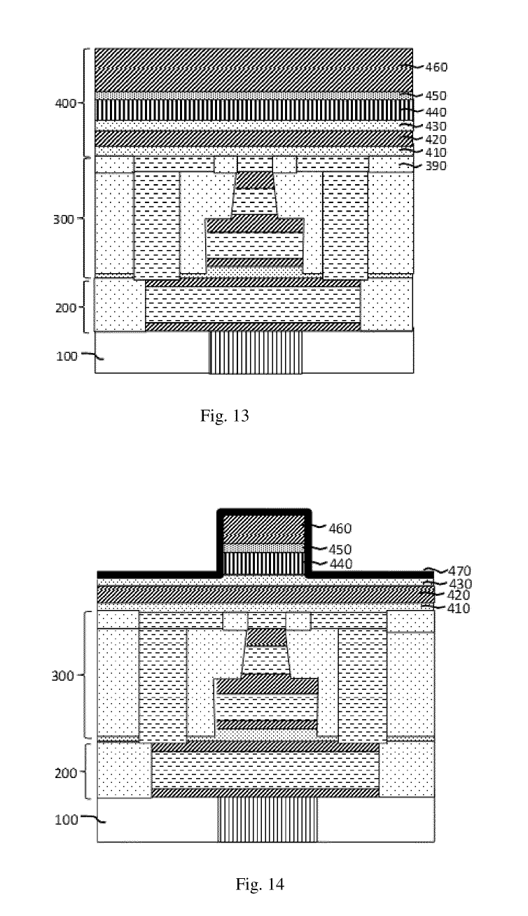

Then the memory cell film stack 400 is deposited, as shown in FIG. 13, which contains a dielectric layer (ILD) 410/a recording layer 420/MgO layer 430/a reference layer 440/Ru cap layer 450/top hard mask Ta layer 460. The ILD layer 410 is either a single MgO layer with a thickness of about 2.5 nm, or bi-layer of AlOx(1 nm)/MgO(2 nm). The magnetic recording layer 420 contains either CoFeB or bi-layer of CoFeB/CoFe, the tunnel barrier layer MgO 430 is about 1 nm, and the magnetic reference (MR) layer 440. A typical material used for reference layer 440 is TbCoFe, CoPd, CoPt. The Ru cap layer 450 has a thickness of 1-2 nm is used to isolate the MR layer from the Ta hard mask layer 460 which has typical thickness of 10-40 nm.

A single or dual photolithography patterning and etch is used to form a small Ta hard mask pillar 460 using a chemical gas (such as CF4) followed by oxygen ashing of the remaining photoresist and RIE redep. Then a chemical gas of CH3OH or CO/NH4 is used to etch the top Ru cap layer 450 and magnetic reference layer 440 and stops in the middle of MgO 430 using the just created Ta hard mask pillar. Immediately after etch, an insulating layer ILD 470 is deposited to conformally cover the exposed MgO junction edge and the entire flat surface, as shown in FIG. 14. The ILD layer 470 can be either a single layer of 6 nm AlOx, a bi-layer of MgO(2 nm)/AlOx(5 nm) or SiN(2 nm)/AlOx(5 nm). The AlOx or SiN can be formed by the ALD method.

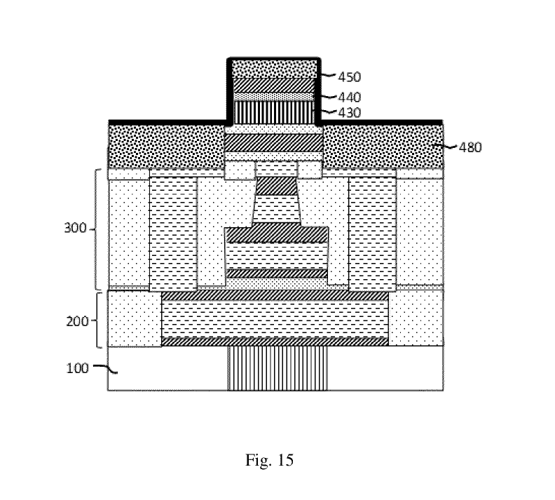

Due to the presence of the ILD layer 410, the recording layer 420 is isolated from the top metal surface of the digital line. In order to connect the recording layer to the underneath bottom electrode, the ILD layer 410 outside the memory pillar must be conductive, which can be done by metal ion implantation to convert the isolated film stack (410-420,430) on the exposed surface outside the memory pillar into a thick conductive layer 480 (FIG. 15). Selection of metal for implantation can be Au, Ag, Cu, Ru, Li. After ion implantation, a high temperature anneal (>200 C degree) is needed to repair the film structure damage due to ion implantation.

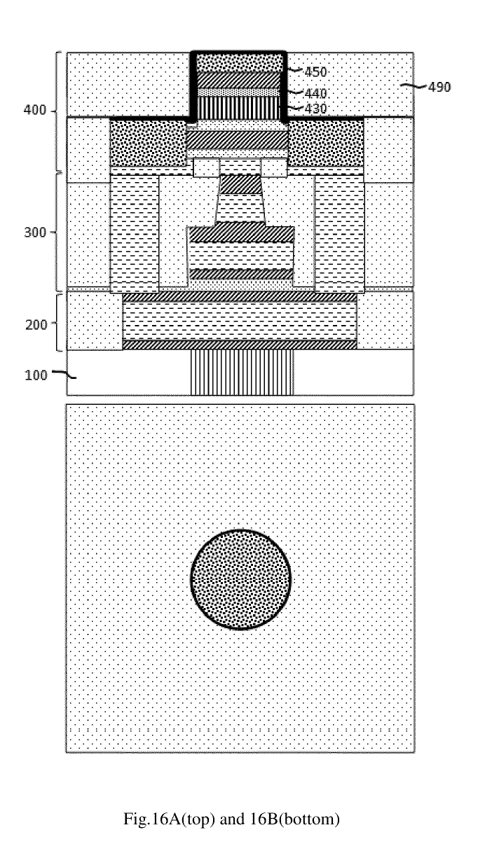

To create an isolated middle conductive base, a photolithography patterning is used to cover the middle memory area before removing the outside conductive surface by etching. After etch, the surface is refilled with dielectric SiO2 layer 490 and CMP to flatten the surface, as shown in FIG. 16.

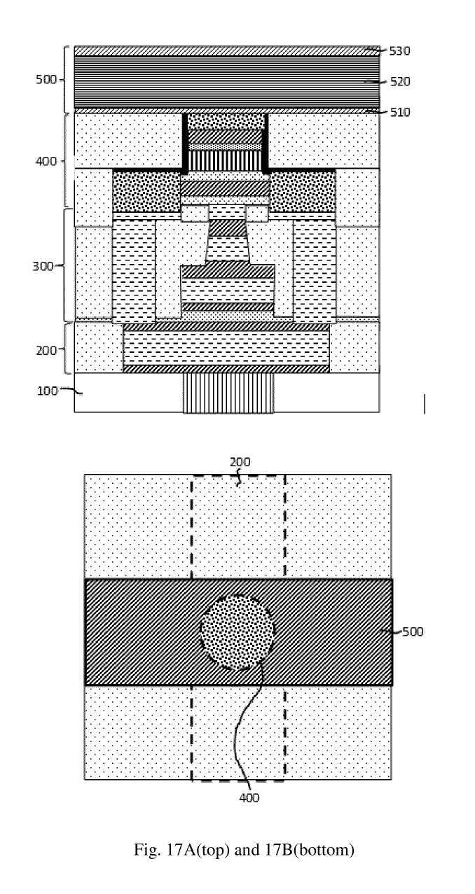

Finally, the top bit line is formed by depositing 5 nm Ta layer 510/50 nm Ru layer 520/10 nm Ta layer 530, patterning, etch, dielectric SiO2 refill and CMP as shown in FIG. 17, which has a magnetic memory cell having an underneath digital line with a metal pillar pointing towards the memory cell and a bit line on the top.

While certain embodiments have been described above, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A method of manufacturing a magnetoresistive memory cell comprising:
a bottom electrode provided on a surface of a substrate and coupled a select transistor through a conductive VIA;
a first interlayer dielectric layer provided on a surface of the bottom electrode;
a digital line provided on a surface of the interlayer dielectric layer;
a second dielectric layer provided on side walls of the digital line;
a dielectric functional layer provided on the top surface of the digital line layer;
a memory recording layer provided on the top surface of the dielectric functional layer having a magnetic anisotropy and a variable magnetization direction and having a induced perpendicular anisotropy from an interface interaction with the functional layer;
a bottom connection layer provided on outside walls of the second dielectric layer and electrically connecting the recording layer and the bottom electrode;
a tunnel barrier layer provided on the top surface of the recording layer;
a magnetic reference layer provided on the top surface of the tunnel barrier having magnetic anisotropy and having a fixed magnetization direction;
a cap layer provided on the top surface of the reference layer as an upper electric electrode;
a bit line provided on the top surface of the cap layer.

2. The element of claim 1, wherein said bottom electrode, comprising a conductive film stack, preferred to be Ta/X/Ta, X is a metal layer having a high conductivity, preferred to be selected from Cu, Ru, Al, Ag, Au, or alloy of them, is formed by a film stack deposition, photolithograph patterning, metal etch, dielectric refill and CMP process.

3. The element of claim 1, wherein said first interlayer dielectric layer is an oxide, nitride or oxynitride, preferred to be Al2O3, SiO2, Si3N4 having a thickness between 5 and 20 nm.

4. The element of claim 1, wherein the magnetic anisotropy of said recording layer is modulated by the voltage between said digital line and said bottom electrode, which could be perpendicular to the plane or lie in the plane.

5. The element of claim 1, wherein said digital line comprises a film stack of Ta/X/Ta/X/Ta, or Ta/NiFe/X/NiFe(optional)/Ta/X/Ta with X being Ru, Cu, Al, Ag, Au, or alloy of them, with bottom Ta thickness between 1-3 nm, middle Ta between 10-40 nm and top Ta thickness between 10-40 nm, X thickness is between 10-50 nm and NiFe thickness between 2-6 nm, wherein the formation process of the said digital line comprises a film stack deposition, a first photolithography patterning, etch processes, a second photolithography patterning, a dielectric refill and a CMP to flatten the surface.

6. The element of claim 5, wherein said first photolithography patterning is a dual photolithography patterning followed by a first etch process using a chemical gas CxFyHz, preferred to be CF4, CF3H to form Ta hard mask, and a second etch process using a chemical gas CH3OH or a mixed chemical gas CO & NH4 to form a top pillar as the top portion of said digital line.

7. The element of claim 5, wherein said second photolithography pattern is a photolithography pattern to define the long stripe digital line comprising a RIE etch process using a chemical gas of CF4 to remove middle Ta layer, a photoresist removal and another RIE etch process using a chemical gas of CH3OH or a mixed gas of CO & NH4 to remove the remaining digital line layer and stop at said first interlayer dielectric layer.

8. The element of claim 5, wherein after said patterning and etch process on said digital line a dielectric material, preferred to be SiO2, is refilled, followed by a CMP process to flatten the top surface.

9. The element of claim 1, further comprising a photolithography patterning process to create a surrounding vertical open space, and said bottom connection layer, preferred to be Ru or Cu, is formed in the open grove by electric plating or atomic layer deposition, followed by a CMP process.

10. The element of claim 1, further comprising a photolithography pattern and etch to create isolated electric contact areas on the top pillar of said digital line and said bottom connection layer.

11. The element of claim 1, said dielectric functional layer, said recording layer, said tunnel barrier layer, said magnetic reference layer, said cap layer and a hard mask layer are deposited subsequently.

12. The element of claim 1, wherein said dielectric functional layer is a single MgO having a thickness between 2-10 nm, or a bi-layer of ALD/MgO with a thickness range of ALD: 1-2 nm, MgO:1-9 nm.

13. The element of claim 1, wherein said recording layer is a CoFeB layer having a thickness between 1-2 nm or a bilayer CoFeB/CoFe having 0.2-0.5 nm thick CoFe as interface dusting layer.

14. The element of claim 1, wherein the said top magnetic reference layer is CoFeB/TbCoFe, CoFeB/CoPt, CoFeB/CoPd, CoFeB/(Co/Pd)n, CoFeB/(Co/Pt)n, with a thickness between 2-6 nm.

15. The element of claim 1, wherein the top capping layer is a Ru layer with a thickness between 1-2 nm.

16. The element of claim 1, wherein the hard mask layer is Ta, or Ta alloy with a thickness between 10-40 nm.

17. The element of claim 1, wherein the memory film stack ILD/memory layer/MgO/reference layer/Ru/Ta is deposited.

18. The element of claim 1, wherein the hard mask etch uses chemical gas CxFyHz, preferred to be CF4, or CF3H, and stop on Ru cap, and the remaining photoresist and associated Ta redep is removed by O2 or Ar/O2.

19. The element of claim 1, wherein the remaining TMR etch uses chemical gases CO & NH4 or CH3OH, C2H5OH, and stops on MgO controlled by the end point signal of MgO.

20. The element of claim 1, wherein the etched TMR junction is quickly conformally covered by a thin of dielectric layer, such as AlOx by atomic layer deposition (ALD), or bi-layer of MgO/ALD, SiN/ALD with a film thickness of 4-8 nm ALD, MgO(1-3 nm)/ALD(4-6 nm), SiN(1-3 nm)/ALD(4-6 nm).

21. The element of claim 1, wherein the ALD on the flat surface is removed by low angle perpendicular ion mill.

22. The element of claim 1, wherein the ALD on the vertical edge surrounding MgO junction is still present after perpendicular ion mill.

23. The element of claim 1, wherein metal ion implantation by Li, Cu, Au, Ru, Pt into the buried ILD region to convert it into an electrically conductive layer.

24. The element of claim 1, wherein another photolithography patterning and etch is used to define an isolate memory cell by removing the conductive layer (formed by ion implantation from the rest of the open area.

25. The element of claim 1, wherein said three terminals magnetic random access memory has a bit line formed on top of memory cell by film deposition Ta/X/Ta or Ta/NiFe/X/NiFe/Ta with X is Ru, Cu, Al, Au, or alloy of them, with bottom Ta thickness between 1-3 nm, middle Ta between 10-40 nm and top Ta thickness between 10-40 nm, X thickness is between 10-50 nm and NiFe thickness between 2-4 nm, wherein the said bit line is formed by patterning and etch to form Ta hard mask using C,H,F containing chemical gas, such as CF4, CF3H and second etch using CH3OH or CO & NH4 to completely etch the remaining film stack, wherein the etched bit line is filled with SiO2 and CMPed to flatten the surface.

26. The element of claim 1, wherein the said three terminals magnetic random access memory is annealed to repair damage film structure by ion implantation with an annealing temperature no less than 200 C degree an annealing time no less than half hour.

27. The element of claim 1, wherein the size of the top pillar of said digital line is small and can create a high electric field during recording.

28. The element of claim 1, wherein said dielectric function layer is a single layer Y made of metal oxide, or nitride, oxynitride, preferred to be selected from MgO, MgZnO, MgN, MgON, having a thickness between 1-3 nm, or a bi-layer Z/Y, Z is made of an oxide, or nitride, oxynitride, preferred to be AlOx or SiOx, having a thickness between 1-2 nm.
